(19) United States
(12) Patent Application Publication
(10) Pub. No.: US 2013/0105758 A1
(43) Pub. Date: May 2, 2013

(54) MEMORY CELL OF RESISTIVE RANDOM ACCESS MEMORY AND MANUFACTURING METHOD THEREOF

(71) Applicant: INDUSTRIAL TECHNOLOGY RESEARCH INSTITUTE, Hsinchu (TW)

(72) Inventors: Heng-Yuan Lee, Hsinchu County (TW); Pei-Yi Gu, Hsinchu County (TW); Yu-Sheng Chen, Taoyuan County (TW)

(73) Assignee: INDUSTRIAL TECHNOLOGY RESEARCH INSTITUTE, Hsinchu (TW)

(21) Appl. No.: 13/719,245

(22) Filed: Dec. 19, 2012

Related U.S. Application Data
(63) Continuation-in-part of application No. 12/334,203, filed on Dec. 12, 2008, now Pat. No. 8,362,454.

(30) Foreign Application Priority Data
Aug. 12, 2008 (TW) 97130654
May 30, 2012 (TW) 101119371

(51) Int. Cl. H01L 45/00

(52) U.S. Cl. CPC H01L 45/145
USPC 257/4; 438/382

(57) ABSTRACT

A memory cell of a resistive random access memory and a manufacturing method thereof are provided. The method includes the following steps. A first electrode is formed. A metal oxide layer is formed on the first electrode. An electrode buffer stacked layer is formed on the metal oxide layer and includes a first buffer layer and a second buffer layer, and the first buffer layer is located between the second buffer layer and the metal oxide layer. An oxidation reaction between the second buffer layer and the metal oxide layer is relatively easier than an oxidation reaction between the first buffer layer and the metal oxide layer. A second electrode layer is formed on the electrode buffer stacked layer.

### CROSS-REFERENCE TO RELATED APPLICATION

This application is a continuation-in-part application of and claims the priority benefit of a prior application Ser. No. 12/334,203, filed on Dec. 12, 2008, now allowed, which claims the priority benefit of Taiwan application serial no. 97130654, filed on Aug. 12, 2008. This application also claims the priority benefit of Taiwan application serial no. 101119371, filed on May 30, 2012. The entirety of each of the above-mentioned patent applications is hereby incorporated by reference herein and made a part of this specification.

### TECHNICAL FIELD

The disclosure relates to a memory cell of a resistive random access memory (RRAM) and a manufacturing method thereof.

### BACKGROUND

A resistive random access memory (RRAM) is a memory device using a material with a resistance characteristic thereof varied along with external influence. Since the resistance is not changed after power-off, the RRAM is a non-volatile memory.

Presently, the RRAM using a single metal electrode as an oxygen atom absorbing layer has been proved to have a variety of excellent memory characteristics, but such type of memory has a problem of that the first time reset current during a current scaling process is excessive. Moreover, although the problem of excessive first time reset current can be overcome when a metal that is difficult to react with oxide is used in the RRAM, the RRAM using such metal has a problem of that the forming voltage is large.

### SUMMARY

The disclosure provides a method for manufacturing a memory cell of a RRAM, which includes the following steps. A first electrode is formed. A metal oxide layer is formed on the first electrode. An electrode buffer stacked layer is formed on the metal oxide layer, where the electrode buffer stacked layer includes a first buffer layer and a second buffer layer, and the first buffer layer is located between the second buffer layer and the metal oxide layer. An oxidation reaction between the second buffer layer and the metal oxide layer is relatively easier than an oxidation reaction between the first buffer layer and the metal oxide layer. A second electrode is formed on the electrode buffer stacked layer.

The disclosure provides a memory cell of a RRAM, which includes a first electrode, a second electrode, a metal oxide layer and an electrode buffer stacked layer. The metal oxide layer is located between the first electrode and the second electrode. The electrode buffer stacked layer is located between the first electrode and the second electrode, where the electrode buffer stacked layer includes a first buffer layer and a second buffer layer, and the first buffer layer is located between the second buffer layer and the metal oxide layer. An oxidation reaction between the second buffer layer and the metal oxide layer is relatively easier than an oxidation reaction between the first buffer layer and the metal oxide layer.

In order to make the aforementioned and other features of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a resistive random access memory (RRAM) according to an embodiment of the disclosure.

FIG. 2 is a schematic diagram of a RRAM according to another embodiment of the disclosure.

FIG. 3 is a diagram illustrating a relationship of voltages and currents of the RRAM.

### DETAILED DESCRIPTION OF DISCLOSED EMBODIMENTS

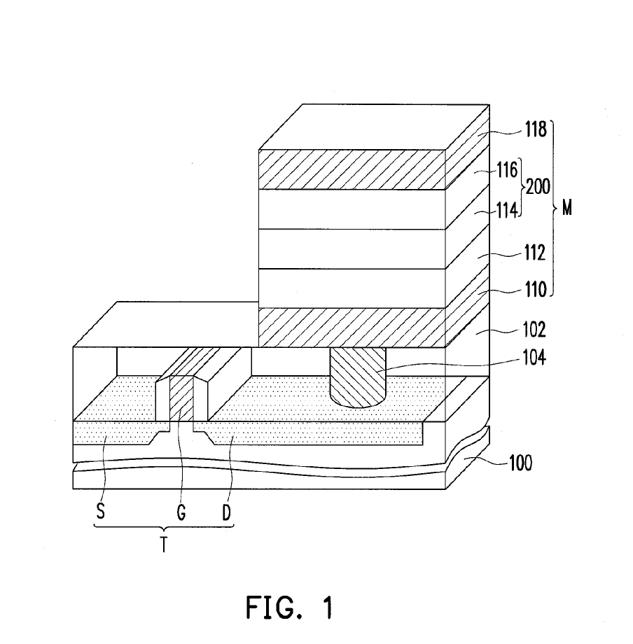

FIG. 1 is a schematic diagram of a resistive random access memory (RRAM) according to an embodiment of the disclosure. In FIG. 1 and the following descriptions, one memory unit in the RRAM is taken as an example for descriptions, and the RRAM includes a plurality of memory units.

Referring to FIG. 1, a method for manufacturing the RRAM of the present embodiment is as follows. A substrate 100 is provided, where the substrate 100 has a control device T formed thereon, which is electrically connected to a bit line (not shown). In the present embodiment, the substrate 100 is, for example, a silicon substrate or other suitable semiconductor substrates. The control device T is, for example, a metal oxide semiconductor (MOS) transistor, which includes a gate G, a source S and a drain D. The type of the control device T is not limited, and other types of semiconductor devices that can be used to control a memory cell of the RRAM can also serve as the control device T.

Then, a memory cell M is formed on the substrate 100. Here, before the memory cell M is formed, an insulation layer 102 is first formed on the substrate 100 to cover the control device T. Then, a contact window 104 is formed in the insulation layer 102, and the contact window 104 is electrically connected to the control device T. Here, the insulation layer 102 may include silicon oxide, silicon nitride, silicon oxynitride, or other suitable insulation materials. A method of forming the contact window 104 is, for example, to pattern the insulation layer 102 though a photolithography and etching process to form a contact window opening (not shown), and then a metal or a conductive material with good conductivity is filled in the contact window opening.

The step of forming the memory cell M includes forming a first electrode 110 on the insulation layer 102. Here, the first electrode 110 is electrically connected to the control device T through the contact window 104, so that the memory cell M is electrically connected to the control device T. The first electrode 110 includes an electrode material capable of blocking diffusion of oxygen atoms. In other words, regarding selection of the material of the first electrode 110, the properties of blocking diffusion of the oxygen atoms and enough thermal stability are generally considered. In this way, in a post heat treatment process, the first electrode 110 can block or barrier diffusion of the oxygen atoms under a temperature condition of the heat treatment. According to the above description, the material of the first electrode 110 preferably includes TaN, TiN, TiAlN, a TiW alloy, Pt, W, Ru or a mixture or a stacked layer of the above materials. Moreover, a thickness of the first electrode 110 is about 5-500 nm.

Then, a metal oxide layer 112 is formed on the first electrode 110 to serve as a variable resistor film of the memory cell M. The metal oxide layer 112 is a binary oxide, and a chemical formula thereof is MxOy, in which M represents Al, Hf, Ti, Ta, Zr or other metal elements capable of presenting resistance transform, and x and y present a stoichiometric ratio or a non-stoichiometric ratio. Here, the so-called stoichiometric ratio refers to that the metal atoms and the oxygen atoms exist in a way of satisfying the stoichiometric, for example, aluminium oxide is Al₂O₃. However, x and y of MxOy of the metal oxide layer 112 are not limited to must satisfy the stoichiometric ratio. According to an embodiment, the resistance-variable metal oxide layer 112 MxOy of the memory cell M is preferably to have a non-stoichiometric ratio between x and y, though the disclosure is not limited thereto.

Then, a first buffer layer 114 is formed on the metal oxide layer 112. Here, a main consideration in selection of a material of the first buffer layer 114 is that such material is not easy to have an oxidation reaction with the metal oxide (the metal oxide layer 112), and is capable of suppressing excessive first time reset current of the memory device. Therefore, the material of the first buffer layer 114 preferably includes Ta, Zr, Hf, Al, Ni, or other metals that are not easy to have the oxidation reaction with the metal oxide layer or a metal oxide of the above metal that is not fully oxidized. Moreover, a thickness of the first buffer layer 114 is 1˜100 nm, which is preferably 1-10 nm.

Then, a second buffer layer 116 is formed on the first buffer layer 114. The first buffer layer 114 and the second buffer layer 116 form an electrode buffer stacked layer 200. A main consideration in selection of a material of the second buffer layer 116 is that such material is easy to have the oxidation reaction with the metal oxide (the metal oxide layer 112) compared to that of the first buffer layer 114. Particularly, the second buffer layer 116 can still have the oxidation reaction with the metal oxide layer 112 in case that the first buffer layer 114 exists. In other words, even if the first buffer layer 114 is sandwiched between the metal oxide layer 112 and the second buffer layer, the second buffer layer 116 can still snatch the oxygen atoms in the metal oxide layer 112. Therefore, the material of the second buffer layer 116 preferably includes Ti, Ta, Zr, Hf, Al, Ni, or other metals that are easy to have the oxidation reaction with the metal oxide layer or a metal oxide of the above metal that is not fully oxidized. For example, if the first buffer layer 114 uses Ta, the second buffer layer 116 may use Ti. Moreover, a thickness of the second buffer layer 116 is 1˜100 nm.

It should he noticed that in order to ensure that the first buffer layer 114 that is not easy to have the oxidation reaction with the metal oxide (the metal oxide layer 112) can suppress the excessive first time reset current of the memory device, and ensure the second buffer layer 116 to have the oxidation reaction with the metal oxide layer 112 in case that the first buffer layer 114 exists, the thickness of the first buffer layer 114 is preferably smaller than the thickness of the second buffer layer 116, though the disclosure is not limited thereto.

Then, a second electrode 118 is formed on the second buffer layer 116, and the second electrode 118 is electrically connected to a word line (not shown). The second electrode 118 includes an electrode material capable of blocking diffusion of oxygen atoms. In other words, regarding selection of the material of the second electrode 118, the properties of blocking diffusion of the oxygen atoms and enough thermal stability are generally considered, and the material is not easy to react with oxygen. According to the above description, the material of the second electrode 118 preferably includes TaN, TiN, Pt, or Ru, and a thickness of the second electrode 118 is about 1˜500 nm.

The first electrode 110, the metal oxide layer 112, the first buffer layer 114, the second buffer layer 116 and the second electrode 118 form the memory cell M. After the memory cell M is formed, a heat treatment process is selectively performed. The heat treatment process includes an annealing processing, a microwave heating processing, an electricity-based oxygen ion migration processing or other suitable heat treatment processes. Moreover, a temperature of the heat treatment process is 200˜800 degrees Celsius. Here, the heat treatment process may prompt the oxidation reaction between the second buffer layer 116 and the metal oxide layer 112.

The RRAM formed according to the above method includes the substrate 100 and the memory cell M. The substrate 100 has the control device T thereon. The memory cell M is disposed on the substrate 100, and is electrically connected to the control device T, where the memory cell M includes the first electrode 110, the metal oxide layer 112, the electrode buffer stacked layer 200 and the second electrode 118. In other words, the structure of the memory cell M from the bottom to the top is sequentially the first electrode 110, the metal oxide layer 112, the first buffer layer 114, the second buffer layer 116 and the second electrode 118.

According to the above descriptions, when the memory cell M operates, a setting voltage (Vset) is applied to the first electrode 110 and the second electrode 118 to transit the metal oxide layer 112 from a high resistance state to a low resistance state. When a reset voltage Vreset is applied to the first electrode 110 and the second electrode 118, the metal oxide layer 112 is transited from the low resistance state to the high resistance state. In other words, the metal oxide resistor film 112 can be programmed so that a dual state memory circuit may have a high resistance or a low resistance, and each memory cell stores data of one bit. Certainly, a plurality of resistance-determined states can be designed in a multi-state memory circuit, so that a single memory cell stores data of a plurality of bits.

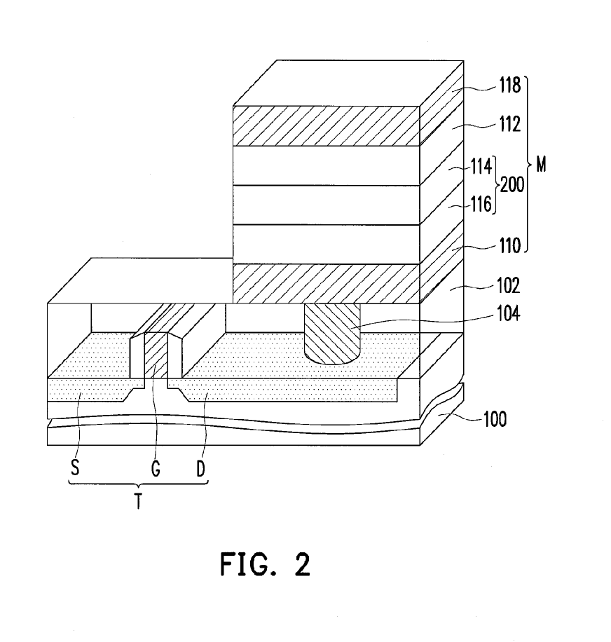

FIG. 2 is a schematic diagram of a RRAM according to another embodiment of the disclosure. Referring to FIG. 2, the RRAM of FIG. 2 is similar to that of FIG. 1, and the same components are denoted by the same symbols, and descriptions thereof are not repeated. In a structure of FIG. 2, the structure of the memory cell M from the bottom to the top is sequentially the first electrode 110, the second buffer layer 116, the first buffer layer 114, the metal oxide layer 112 and the second electrode 118, where the second buffer layer 116 and the first buffer layer 114 form the electrode buffer stacked layer 200.

In the present embodiment, since the first buffer layer 114 that is not easy to have the oxidation reaction with the metal oxide is mainly used to suppress the excessive first time reset current of the memory device, the first buffer layer 114 is disposed between the metal oxide layer 112 and the second buffer layer 116. Moreover, in order to ensure that the second buffer layer 116 that is easy to have the oxidation reaction with the metal oxide may still have the oxidation reaction with the metal oxide layer 112 even if the first buffer layer 114 exists, the thickness of the first buffer layer 114 is preferably smaller than the thickness of the second buffer layer 116, though the disclosure is not limited thereto.

Moreover, in the embodiment of FIG. 2, after the memory cell M is formed, a heat treatment process can also be selectively performed. The heat treatment process includes an annealing processing, a microwave heating processing, an electricity-based oxygen ion migration processing or other suitable heat treatment processes. Moreover, a temperature of the heat treatment process is 200˜800 degrees Celsius. Here, the heat treatment process may prompt the oxidation reaction between the second buffer layer 116 and the metal oxide layer 112.

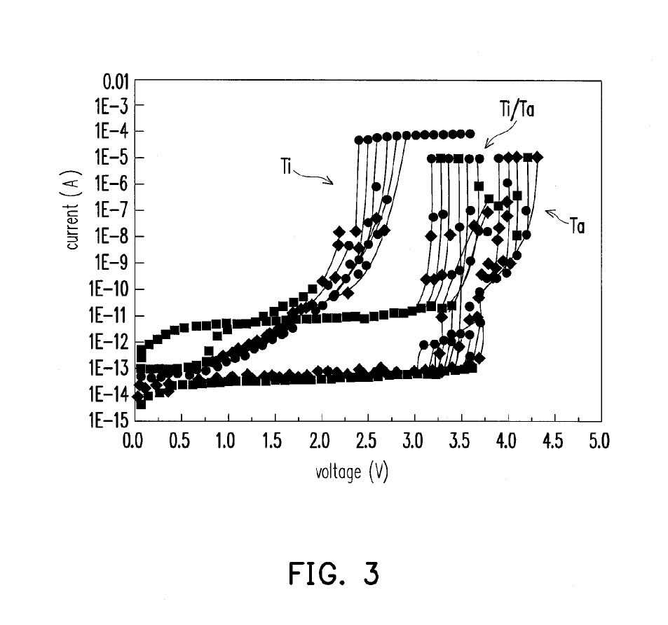

FIG. 3 is a diagram illustrating a relationship of voltages and currents of the RRAM. In FIG. 3, a plurality of curves (marked as Ti) to the left represent voltage-current curves of the memory cell of the RRAM in which a single layer of Ti is purely used to serve as the electrode buffer layer. A plurality of curves (marked as Ta) to the left represent voltage-current curves of the memory cell of the RRAM in which a single layer of Ta is purely used to serve as the electrode buffer layer. A plurality of curves (marked as Ti/Ta) in the middle represent voltage-current curves of the memory cell of the RRAM in which a stacked layer of Ti/Ta is used to serve as the electrode buffer layer.

According to FIG. 3, it is known that when the memory cell of the RRAM purely uses the single layer of Ti to serve as the electrode buffer layer, although the forming voltage of the memory cell is relatively low, it has a problem of inadequate reliability of the memory device. When the memory cell of the RRAM purely uses the single layer of Ta to serve as the electrode buffer layer, although the reliability of the memory device is improved, the forming voltage of the memory cell is excessively high. When the memory cell of the RRAM purely uses the stacked layer of Ti/Ta to serve as the electrode buffer layer, the reliability of the memory device and the forming voltage of the memory cell are both taken into consideration.

In summary, in the memory cell of the RRAM of the disclosure, the first buffer layer and the second buffer layer are used as electrode buffer layers. Particularly, the first buffer layer is not easy to have the oxidation reaction with the metal oxide, so that the first time reset current of the memory is decreased to improve reliability of the memory device. Moreover, the second buffer layer is easy to have the oxidation reaction with the metal oxide, so that the forming voltage of the memory device is decreased.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A method for manufacturing a memory cell of a resistive random access memory, comprising:
forming a first electrode;
forming a metal oxide layer on the first electrode;
forming an electrode buffer stacked layer on the metal oxide layer, wherein the electrode buffer stacked layer comprises a first buffer layer and a second buffer layer, the first buffer layer is located between the metal oxide layer and the second buffer layer, and an oxidation reaction between the second buffer layer and the metal oxide layer is relatively easier than an oxidation reaction between the first buffer layer and the metal oxide layer; and
forming a second electrode on the electrode buffer stacked layer.

2. The method for manufacturing the memory cell of the resistive random access memory as claimed in claim 1, wherein after the second electrode is formed, the method further comprises performing a heat treatment process.

3. The method for manufacturing the memory cell of the resistive random access memory as claimed in claim 1, wherein the heat treatment process comprises an annealing processing, a microwave heating processing, or an electricity-based oxygen ion migration processing, and a temperature of the heat treatment process is 200˜800 degrees Celsius.

4. The method for manufacturing the memory cell of the resistive random access memory as claimed in claim 1, wherein the first buffer layer comprises Ta, Zr, Hf, Al, Ni, or a metal oxide of the above metal that is not fully oxidized, and a thickness of the first buffer layer is 1˜100 nm.

5. The method for manufacturing the memory cell of the resistive random access memory as claimed in claim 1, wherein the second buffer layer comprises Ti, Ta, Zr, Hf, Al, Ni, or a metal oxide of the above metal that is not fully oxidized, and a thickness of the second buffer layer is 1˜100 nm.

6. The method for manufacturing the memory cell of the resistive random access memory as claimed in claim 1, wherein a thickness of the first buffer layer is smaller than a thickness of the second buffer layer.

7. The method for manufacturing the memory cell of the resistive random access memory as claimed in claim 1, wherein the first electrode and the second electrode respectively comprise an electrode material capable of blocking diffusion of oxygen atoms.

8. The method for manufacturing the memory cell of the resistive random access memory as claimed in claim 7, wherein the first electrode comprises TaN, TiN, TiAlN, a TiW alloy, Pt, W, Ru or a mixture or a stacked layer of the above materials, and a thickness thereof is about 1˜500 nm.

9. The method for manufacturing the memory cell of the resistive random access memory as claimed in claim 7, wherein the second electrode comprises TaN, TiN, Pt, or Ru, and a thickness thereof is about 1˜500 nm.

10. The method for manufacturing the memory cell of the resistive random access memory as claimed in claim 1, wherein a chemical formula of the metal oxide layer is MxOy, in which M represents Al, Hf, Ti, Ta or Zr, and x and y present a stoichiometric ratio or a non-stoichiometric ratio.

11. A memory cell of a resistive random access memory, comprising:
a first electrode and a second electrode;
a metal oxide layer, located between the first electrode and the second electrode; and
an electrode buffer stacked layer, located between the first electrode and the second electrode, wherein the electrode buffer stacked layer comprises a first buffer layer and a second buffer layer, the first buffer layer is located between the metal oxide layer and the second buffer layer, and an oxidation reaction between the second buffer layer and the metal oxide layer is relatively easier than an oxidation reaction between the first buffer layer and the metal oxide layer.

12. The memory cell of the resistive random access memory as claimed in claim 11, wherein a structure of the memory cell from the bottom to the top is sequentially the first electrode, the metal oxide layer, the first buffer layer, the second buffer layer and the second electrode.

13. The memory cell of the resistive random access memory as claimed in claim 11, wherein a structure of the memory cell from the bottom to the top is sequentially the first electrode, the second buffer layer, the first buffer layer, the metal oxide layer and the second electrode.

14. The memory cell of the resistive random access memory as claimed in claim 11, wherein the first buffer layer comprises Ta, Zr, Hf, Al, Ni, or a metal oxide of the above metal that is not fully oxidized, and a thickness of the first buffer layer is 1˜100 nm.

15. The memory cell of the resistive random access memory as claimed in claim 11, wherein the second buffer layer comprises Ti, Ta, Zr, Hf, Al, Ni, or a metal oxide of the above metal that is not fully oxidized, and a thickness of the second buffer layer is 1˜100 nm.

16. The memory cell of the resistive random access memory as claimed in claim 11, wherein a thickness of the first buffer layer is smaller than a thickness of the second buffer layer.

17. The memory cell of the resistive random access memory as claimed in claim 11, wherein the first electrode and the second electrode respectively comprise an electrode material capable of blocking diffusion of oxygen atoms.

18. The memory cell of the resistive random access memory as claimed in claim 17, wherein the first electrode comprises TaN, TiN, TiAlN, a TiW alloy, Pt, W, Ru or a mixture or a stacked layer of the above materials, and a thickness thereof is about 1˜500 nm.

19. The memory cell of the resistive random access memory as claimed in claim 17, wherein the second electrode comprises TaN, TiN, Pt, or Ru, and a thickness thereof is about 1˜500 nm.

20. The memory cell of the resistive random access memory as claimed in claim 11, wherein a chemical formula of the metal oxide layer is MxOy, in which M represents Al, Hf, Ti, Ta or Zr, and x and y present a stoichiometric ratio or a non-stoichiometric ratio.
